(19) United States
(12) Patent Application Publication
(10) Pub. No.: US 2013/0113559 A1
(43) Pub. Date: May 9, 2013

(54) DEVICE AND METHOD FOR PRE-DISTORTING AND AMPLIFYING A SIGNAL BASED ON AN ERROR ATTRIBUTE

(71) Applicants: Doron KOREN, Kefar Sirkin (IL); Sergey TOUJIKOV, Rishon Le zion (IL); Ofer LEVY, Ness-Ziona (IL)

(72) Inventors: Doron KOREN, Kefar Sirkin (IL); Sergey TOUJIKOV, Rishon Le zion (IL); Ofer LEVY, Ness-Ziona (IL)

(73) Assignee: VYYCORE LTD., Petach Tikva (IL)

(21) Appl. No.: 13/357,674

(22) Filed: Jan. 25, 2012

Related U.S. Application Data
(60) Provisional application No. 61/556,849, filed on Nov. 8, 2011.

(51) Int. Cl. H03F 1/26

(52) U.S. Cl. 330/149

(57) ABSTRACT

A method and a device may be provided. The device may include a non-linear amplifying circuit arranged to apply a non-linear gain function on an analog signal to provide an amplified signal; an input circuit, arranged to clip I channel and Q channel digital input signals supplied from a digital transmitter, to provide clipped I-channel and Q-channel digital signals; a pre-distortion circuit, arranged to pre distort the clipped I channel and Q channel digital signals such as to at least partially compensate for a non linearity of the non linear gain function, to provide pre-distorted I-channel and Q-channel digital signals; a mixed signal circuit for converting the pre-distorted I-channel and Q-channel digital signals to the analog signal; a reconstruction circuit, arranged to receive at least a portion of the amplified signal and to generate reconstructed I-channel and Q-channel signals; and a control circuit, arranged to: calculate an error attribute based on (a) the clipped I-channel and Q-channel digital signals, and (b) the reconstructed digital I-channel and Q-channel signals; and to affect at least one operational parameter of the non-linear amplifying circuit in response to the error attribute.

### RELATED APPLICATION

This application claims the priority of U.S. provisional patent No. 61/556849 filing date Nov. 8, 2011 which is incorporated herein by reference.

### BACKGROUND OF THE INVENTION

Power amplifiers which amplify electric signals may be characterized by non-linearity of the amplification, usually (though not necessarily) when the signal inputted to the amplifier comes closer to a saturation threshold of the amplifier. The non-linearity is indicative of a deviation of the amplification process from a linear amplification process during which the amplification involves amplifying an input signal by a constant amplification factor. Most pre-distortion mechanism require the same clock rate of the analog to digital converter and the digital to analog converter. This drawback leads to a major current consumption on the analog to digital converter. The device and method presented in this application solve this problem.

Preprocessing of the input signal before it reaches the amplifier (also known as pre-distorting) may be implemented to overcome such non-linearity.

Various processes including pre-distortion, non-linear amplification and other mixed signal operations may cause degradation in the quality of the amplified signal.

Pre-shipment calibration of semiconductor non-linear amplifiers and pre-distortion circuits can be costly and the manufacturer of these non-linear amplifiers and pre-distortion circuits can be reluctant from performing such calibrations. In addition, process variations and other factors (such as ambient temperature) can cause in mismatches between the non-linear amplifiers and pre-distortion circuits that are hard to predict during the manufacturing process.

There is a growing need to provide a device and method for reducing and even minimizing the quality degradation of amplified signals.

### SUMMARY

According to an embodiment of the invention a device is provided. The device may include a non-linear amplifying circuit arranged to apply a non-linear gain function on an analog signal to provide an amplified signal; an input circuit, arranged to clip I-channel and Q-channel digital input signals supplied from a digital transmitter, to provide clipped I-channel and Q-channel digital signals; a pre-distortion circuit, arranged to pre-distort the clipped I-channel and Q-channel digital signals such as to at least partially compensate for a non-linearity of the non-linear gain function, to provide pre-distorted I-channel and Q-channel digital signals; a mixed signal circuit for converting the pre-distorted I-channel and Q-channel digital signals to the analog signal; a reconstruction circuit, arranged to receive at least a portion of the amplified signal and to generate reconstructed I-channel and Q-channel signals; and a control circuit, arranged to: calculate an error attribute based on at least one of the (a) the clipped I-channel and Q-channel digital signals, and (b) the reconstructed digital I-channel and Q-channel signals; and to affect at least one operational parameter of the non-linear amplifying circuit in response to the error attribute.

The control circuit may be arranged to affect at least one operational parameter of the non linear amplifying circuit and at least one operational parameter of at least one additional entity out of the input circuit, the pre-distortion circuit, and the mixed signal circuit.

The at least one operational parameter may include a gain, a bias voltage, a saturation power or a combination thereof. The at least one operational parameter can be affected by changing a signal provided such as a current, a voltage or a command.

The control circuit may be arranged to perform multiple iterations of affecting the at least one operational parameter and calculating the error attribute.

The control circuit may be arranged to perform multiple iterations of affecting the at least one operational parameter and calculating the error attribute until finding an optimal value of the at least one operational parameter. This optimal value can be the best value out of the values of operational parameters out of those tested during the multiple iterations. The best can be determined based on the error attribute—usually minimizing the error will be considered to the best value of the operational parameter.

The control circuit may be arranged to affect at least one operational parameter of multiple entities out of the non linear amplifying circuit, the input circuit, the pre-distortion circuit, and the mixed signal circuit.

The control circuit may be arranged to calculate the error attribute based on a ratio between (i) a difference between a power attribute of the clipped I-channel and Q-channel digital signals and a power attribute of the reconstructed digital I-channel and Q-channel signals; and (ii) the power attribute of the clipped I-channel and Q-channel digital signals.

The control circuit may be arranged to calculate the error attribute by: calculating auto-correlations of the clipped I-channel and Q-channel digital signals to provide auto-correlation results; calculating cross-correlations between the clipped I-channel and Q-channel digital signals and the reconstructed digital I-channel and Q-channel signals to provide cross-correlation results; and calculating a pre-defined relationship between the auto-correlation results and the cross-correlation results.

The device may include I-channel and Q-channel digital multipliers that precede a clipping circuit of the input circuit; and wherein the control circuit may be arranged to affect an operational parameter of each of the I-channel and Q-channel digital multipliers.

The device may include I-channel and Q-channel digital multipliers that precede a clipping circuit of the input circuit; and wherein the control circuit is further arranged to affect at least one operational parameter of each of the I-channel and Q-channel digital multipliers.

The control circuit may be arranged to affect the gain of each of the I-channel and Q-channel digital multipliers and the gain of the non-linear amplifying circuit while maintaining an overall transmission gain of the device substantially unchanged.

The control circuit may be arranged to affect the at least one operational parameter of each of the I-channel and Q-channel digital multipliers and the at least one operational parameter of the non-linear amplifying circuit while maintaining a value of at least one overall operational parameter of the device substantially unchanged.

The non-linear amplifying circuit may include a non-linear amplifier and a pre-amplifier; wherein the control circuit may be arranged to affect an operational parameter of the pre-amplifier.

The mixed signal circuit may include at least one pair of I-channel and Q-channel multipliers; wherein the control circuit may be arranged to control at least one operational parameter of at least one pair of I-channel and Q-channel multipliers.

The input circuit may be arranged to apply clipping operations and low-pass filtering operations on the I-channel and Q-channel digital input signals to provide the clipped I-channel and Q-channel digital signals; wherein the clipping operations precede the low-pass filtering operations.

The pre-distortion circuit may be arranged to select a selected set of pre-distortion coefficient values, based on attributes of the clipped I-channel and Q-channel digital signals; and to apply the selected set of the pre-distortion coefficient values to provide the pre-distorted I-channel and Q-channel digital signals.

The control circuit may be arranged to affect gains of multiple components of the device while maintaining an operating point of a non-linear amplifier of the non-linear amplifying circuit substantially unchanged.

A method for generating an amplified signal may be provided and may include :clipping, by an input circuit, I-channel and Q-channel digital input signals supplied from a digital transmitter, to provide clipped I-channel and Q-channel digital signals; pre-distorting, by a pre-distortion circuit, the clipped I-channel and Q-channel digital signals such as to at least partially compensate for a non-linearity of a non-linear gain function applied by a non-linear amplifying circuit, to provide pre-distorted I-channel and Q-channel digital signals; converting, by a mixed signal circuit, the pre-distorted I-channel and Q-channel digital signals to the analog signal; amplifying, by the non-linear amplifying circuit, the analog circuit by applying the non-linear gain function; generating, by a reconstruction circuit, and in response to at least a portion of the amplified signal, reconstructed I-channel and Q-channel signals; calculating, by a control circuit, an error attribute based on at least one of the (a) the clipped I-channel and Q-channel digital signals, and (b) the reconstructed digital I-channel and Q-channel signals; and affecting, by the control circuit, at least one operational parameter of the non-linear amplifying circuit in response to the error attribute.

The method, may include affecting the at least one operational of the non linear amplifying circuit and affecting at least one operational parameter of at least one additional entity out of the input circuit, the pre-distortion circuit, and the mixed signal circuit.

The at least one operational parameter may include a gain, a bias voltage, a saturation power or a combination thereof. The at least one operational parameter can be affected by changing a signal provided such as a current, a voltage or a command.

The method may include performing multiple iterations of affecting the at least one operational parameter and calculating the error attribute.

The method may include performing multiple iterations of affecting the at least one operational parameter and calculating the error attribute until finding an optimal value of the at least one operational parameter.

The method may include affecting at least one operational parameter of multiple entities out of the non linear amplifying circuit, the input circuit, the pre-distortion circuit, and the mixed signal circuit.

The method may include calculating the error attribute based on a ratio between (a) a difference between a power attribute of the clipped I-channel and Q-channel digital signals and a power attribute of the reconstructed digital I-channel and Q-channel signals; and (b) the power attribute of the clipped I-channel and Q-channel digital signals.

The method may include calculating the error attribute by: calculating auto-correlations of the clipped I-channel and Q-channel digital signals to provide auto-correlation results; calculating cross-correlations between the clipped I-channel and Q-channel digital signals and the reconstructed digital I-channel and Q-channel signals to provide cross-correlation results; and calculating a pre-defined relationship between the auto-correlation results and the cross-correlation results.

The input circuit may include a clipping circuit that is preceded by I-channel and Q-channel digital multipliers. The method may include affecting an operational parameter of each of the I-channel and Q-channel digital multipliers.

The input circuit may include a clipping circuit that is preceded by I-channel and Q-channel digital multipliers. The method may include affecting at least one operational parameter of each of the I-channel and Q-channel digital multipliers.

The method may include affecting the gain of each of the I-channel and Q-channel digital multipliers and the gain of the non-linear amplifying circuit while maintaining an overall transmission gain of the device substantially unchanged.

The method may include affecting the at least one operational parameter of each of the I-channel and Q-channel digital multipliers and the at least one operational parameter of the non-linear amplifying circuit while maintaining a value of at least one overall operational parameter of the device substantially unchanged.

The non-linear amplifying circuit may include a non-linear amplifier and a pre-amplifier. The method may include affecting an operational parameter of the pre-amplifier.

The mixed signal circuit may include at least one pair of I-channel and Q-channel multipliers. The method may include control at least one operational parameter of at least one pair of I-channel and Q-channel multipliers.

The method may include applying clipping operations and filtering operations, by the input circuit, on the I-channel and Q-channel digital input signals to provide the clipped I-channel and Q-channel digital signals; wherein the clipping operations precede the low-pass filtering operations.

The method may include selecting a selected set of pre-distortion coefficient values, based on attributes of the clipped I-channel and Q-channel digital signals; and applying the selected set of the pre-distortion coefficient values to provide the pre-distorted I-channel and Q-channel digital signals.

The method may include affecting gains of multiple components of the device while maintaining an operating point of a non-linear amplifier of the non-linear amplifying circuit substantially unchanged.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a device, according to an embodiment of the invention;

FIG. 2 illustrates various portions of the device of FIG. 1, according to an embodiment of the invention;

FIG. 3 illustrates a method, according to an embodiment of the invention;

FIG. 4 illustrates a stage of the method of FIG. 3, according to an embodiment of the invention;

FIG. 5 illustrates a method, according to an embodiment of the invention;

FIG. 6 illustrates a stage of the method of FIG. 5, according to an embodiment of the invention;

FIG. 7 illustrates a device, according to an embodiment of the invention; and

FIG. 8 illustrates a method, according to an embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

There are provided devices, methods and computer readable mediums for compensating (at least partially) for mismatches or other errors in a device that includes a pre-distortion circuit and a non-linear amplification circuit. The compensating process may be executed once, in a periodical manner, in a random manner, in a pseudo-random manner, and additionally or alternatively, in response to an event such as a malfunction, increased distortions, changes in an ambient temperature and the like. The compensating process can include one or more iterations of (i) calculating an error attribute, and (ii) affecting at least one operational parameter of (at least) the non-linear amplification circuit based on the error attribute. Multiple iterations can provide multiple error attributes that can be processed to determine the optimal one or more operational parameters. The operational parameters can be changed (for example slightly changed about a working point) until finding a desired (for example- a local optimum) operational parameter. Slight changes can be defined as being a fraction (less than 1/N, wherein N can be 2,3,4,5,6,7,8 or more) of the value of the operational parameter.

An error attribute can be calculated in any one of the methods and by any one of the device. The error attribute can be calculated based on at least one of the (a) the clipped I-channel and Q-channel digital signals, and (b) the reconstructed digital I-channel and Q-channel signals. It is noted that the error attribute can include calculating a ratio between (a) and (b) or applying any other function. The error attribute can be calculated by detecting interferences, artifcats or noises in the reconstructed digital I-channel and Q-channel signals. This can include performing a time to frequency domain conversion of the reconstructed digital I-channel and Q-channel signals and looking for out of band noises—signals that are located out of a desired frequency range of the reconstructed digital I-channel and Q-channel signals.

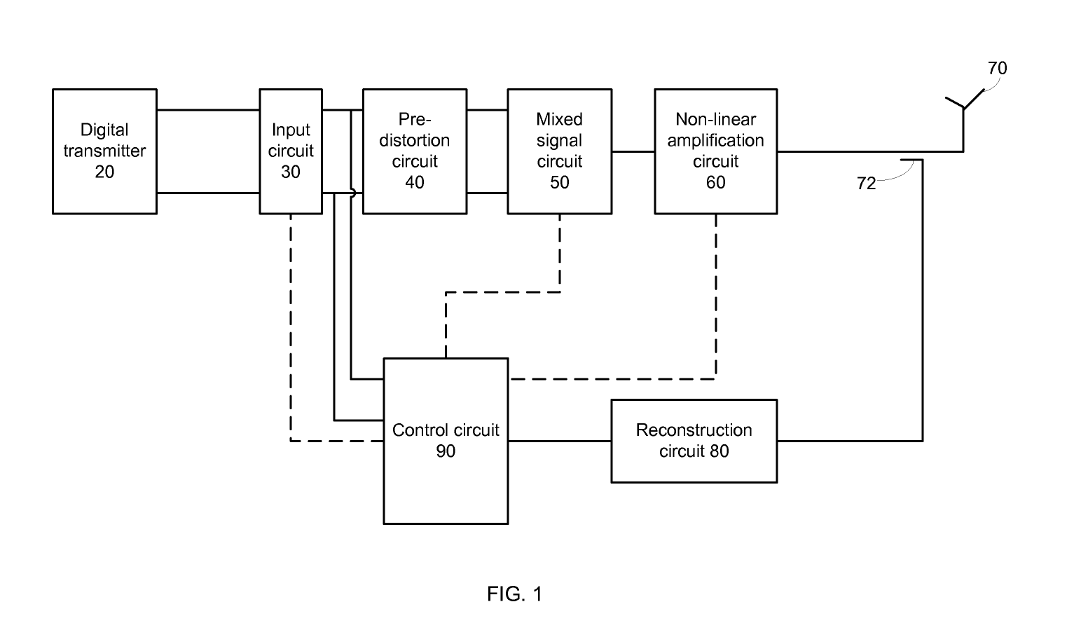

FIG. 1 illustrates device 10, according to an embodiment of the invention.

Device 10 may include:
i. A non-linear amplifying circuit 60 arranged to apply a non-linear gain function on an analog signal to provide an amplified signal.
ii. An input circuit 30 arranged to clip I-channel and Q-channel digital input signals supplied from a digital transmitter, to provide clipped I-channel and Q-channel digital signals.
iii. A pre-distortion circuit 40, arranged to pre-distort the clipped I-channel and Q-channel digital signals such as to at least partially compensate for a non-linearity of the non-linear gain function, to provide pre-distorted I-channel and Q-channel digital signals.
iv. A mixed signal circuit 50 for converting the pre-distorted I-channel and Q-channel digital signals to the analog signal.
v. A reconstruction circuit 80, arranged to receive at least a portion of the amplified signal and to generate reconstructed I-channel and Q-channel signals.
vi. A control circuit 90, arranged to: calculate an error attribute based on (a) the clipped I-channel and Q-channel digital signals, and (b) the reconstructed digital I-channel and Q-channel signals; and affect a gain of at least one components of the device in response to the error attribute. The control circuit can also determine not to affect any gain base don the error attribute.

FIG. 1 also illustrates device 10 as including:
i. A digital transmitter 20 arranged to supply the I-channel and Q-channel digital input signals.
ii. An antenna 70 for wirelessly transmitting the amplified signal.
iii. A coupler 72 for providing a fraction of the amplified signal to the reconstruction circuit.

The digital transmitter 20 is connected to the input circuit 30. The input circuit 30 is connected to the control circuit 90 and to the pre-distortion circuit 40. The mixed signal circuit 50 is connected between the pre-distortion circuit 40 and the non-linear amplifying circuit 60. The non-linear amplifying circuit 60 is also connected to antenna 70 and to coupler 72. The reconstruction circuit 80 is connected between the coupler 72 and the control circuit 90.

The control circuit 90 can control the gain of various components of the device 10, as illustrated by dashed arrows that connect the control circuit 90 to input circuit 30, mixed signal circuit 50 and non-linear amplifying circuit 60. It is noted that each of these mentioned components (39, 50 and 60) can include one or more adjustable gain components (such as amplifiers, multipliers, and the like) that can be independently controlled by the control circuit 90.

The control circuit 90 may determine to affect the gain of a component of the device 10 in order to obtain a desired error attribute. The control circuit 90 can aim to minimize the error attribute or at least reduce it (Assuming that lower error attribute values represent lower signal distortion or lower transmission path imperfection).

The control circuit 90 can calculate the error attribute, determine whether to change a gain of one or more components of the device 10 and then affect the gain of zero or more components—based on the determination.

The control circuit 90 may be arranged to calculate the error attribute based on a ratio between a difference between a power attribute of the clipped I-channel and Q-channel digital signals and a power attribute of the reconstructed digital I-channel and Q-channel signals; and the power attribute of the clipped I-channel and Q-channel digital signals.

The control circuit 90 may be arranged to calculate the error attribute by: calculating auto-correlations of the clipped I-channel and Q-channel digital signals to provide auto-correlation results; calculating cross-correlations between the clipped I-channel and Q-channel digital signals and the reconstructed digital I-channel and Q-channel signals to provide cross-correlation results; and calculating a pre-defined relationship between the auto-correlation results and the cross-correlation results.

According to an embodiment of the invention it may be desired to operate a non-linear amplifier of the non-linear amplifying circuit at the same working point. The control circuit may alter gains of two or more components in order to allow the non-linear amplifier to continue operating at the same working point.

According to an embodiment of the invention the control circuit 90 may be arranged to calculate an error attribute based on (a) the clipped I-channel and Q-channel digital signals, and (b) the reconstructed digital I-channel and Q-channel signals; and to affect at least one operational parameter of the non-linear amplifying circuit 60 in response to the error attribute.

The control circuit 90 may be arranged to affect at least one operational parameter of the non linear amplifying circuit 60 and at least one operational parameter of at least one additional entity out of the input circuit 30, the pre-distortion circuit 40, and the mixed signal circuit 50.

The at least one operational parameter may include a gain, a bias voltage, a saturation power or a combination thereof. The at least one operational parameter can be affected by changing a signal provided such as a current, a voltage or a command.

The control circuit 90 may be arranged to perform multiple iterations of affecting the at least one operational parameter and calculating the error attribute.

The control circuit 90 may be arranged to perform multiple iterations of affecting the at least one operational parameter and calculating the error attribute until finding an optimal value of the at least one operational parameter. This optimal value can be the best value out of the values of operational parameters out of those tested during the multiple iterations. The best value can be determined based on the error attribute—usually minimizing the error will be considered to the best value of the operational parameter.

The control circuit 90 may be arranged to affect at least one operational parameter of multiple entities out of the non linear amplifying circuit 60, the input circuit 30, the pre-distortion circuit 40, and the mixed signal circuit 50.

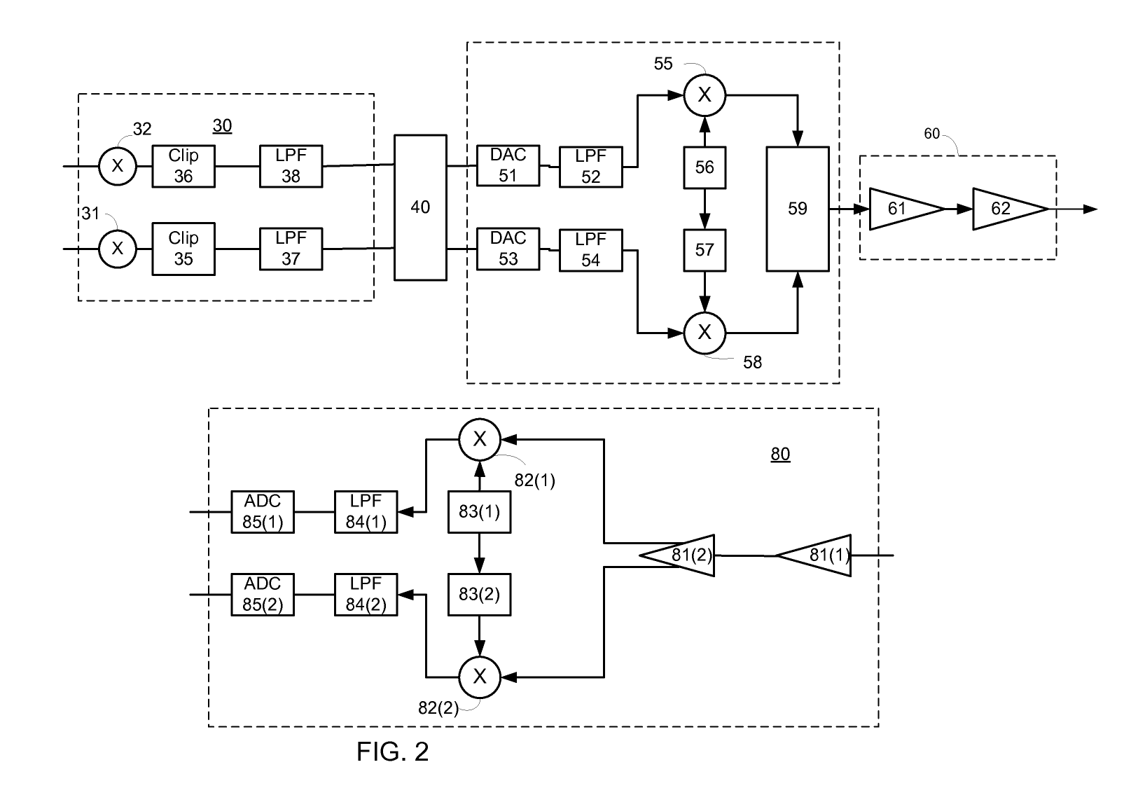

FIG. 2 illustrates various portions of the device of FIG. 1, according to an embodiment of the invention.

Input circuit 30 is illustrates as including an I-channel input path and a Q-channel input path. The I-channel input path includes an I-channel digital multiplier 32, an I-channel clipping circuit 36 and a low pass filter 38. The Q-channel input path includes a Q-channel digital multiplier 31, a Q-channel clipping circuit 35 and a low pass filter 37.

The mixed signal circuit 50 is illustrated as including I-channel and Q-channel digital to analog converters (DACs) 51 and 53, I-channel and Q-channel low pass filters 52 and 54, I-channel and Q-channel mixers 55 and 58, local oscillator 56, ninety degrees phase shifter 75 and combiner 59.

The I-channel and Q-channel DACs 51 and 53 are connected between the pre-distortion circuit 40 and the I-channel and Q-channel low pass filters 52 and 54. The outputs of the I-channel and Q-channel low pass filters 52 and 54 are connected to first inputs of the I-channel and Q-channel mixers 55 and 58. The local oscillator 56 is connected to the ninety degrees phase shifter 57 and to a second input of the I-channel mixer 55. An output of the ninety degrees phase shifter 75 is connected to a second input of the ninety degrees phase shifter 57.The outputs of the I-channel and Q-channel mixers 55 and 58 are connected to the combiner 59. The output of the combiner 59 is connected to the input of the non-linear amplifying circuit 60.

I-channel and Q-channel DACs 51 and 53 convert pre-distorted I-channel and Q-channel digital signals to pre-distorted I-channel and Q-channel analog signals. I-channel and Q-channel low pass filters 52 and 54 filter the pre-distorted I-channel and Q-channel digital signals to provide pre-distorted low-pass filtered I-channel and Q-channel analog signals.

The pre-distorted low-pass filtered I-channel and Q-channel analog signals and up-converted and phase-shifted by I-channel and Q-channel mixers 55 and 58, local oscillator 56 and the ninety degrees phase shifter 57, to provide I-channel and Q-channel analog signals that are combined by combiner 59 to provide an analog signal.

The analog signal is provided to gain controllable pre-amplifier 61 that pre-amplifies the analog signal to provide to the non-linear amplifier 62 an analog pre-distorted signal that in turn is amplified to provide an amplified signal.

Thus, the transmission path (that may include input circuit 20, pre-distortion circuit 40, mixed signal circuit 50 and non-linear amplification circuit 60) may process each pair of I-channel and Q-channel digital input signals to provide an amplified signal.

Referring to FIG. 2, the control circuit can control the gain of each of the I-channel digital multiplier 32, the Q-channel digital multiplier 31, pre-amplifier 61, I-channel and Q-channel mixers 55 and 58 (that may include an additional input for receiving gain control signal), and the like. It is noted that the pre-distortion circuit 40 may have gain controllable components and that each of the mixed signal circuit 50 and the input circuit 30 can have additional controllable gain components that are not shown for simplicity of explanation.

It is noted that the control circuit 90 can perform at least one of the following or a combination thereof:
i. Affect a gain of each of I-channel and Q-channel digital multipliers 32 and 31 that precede the input clipping circuit.
ii. Affect a gain of the non-linear amplifying circuit 60.
iii. Affect the gain of each of the I-channel and Q-channel digital multipliers 32 and 31 and the gain of the non-linear amplifying circuit 60 while maintaining an overall transmission gain of the device substantially unchanged.
iv. Affect a gain of a pre-amplifier 61 of the non-linear amplifying circuit 60, wherein the pre-amplifier precedes a non-linear amplifier 62.
v. Affect a gain of at least one pair of I-channel and Q-channel multipliers (not shown) of the mixed signal circuit. These I-channel and Q-channel multipliers can be implemented by adding an input to the I-channel and Q-channel mixers 55 and 58 or having additional I-channel and Q-channel multipliers.
vi. Affect gains of multiple components of the device 10 while maintaining an operating point of the non-linear amplifier 62 substantially unchanged. Thus, the non-linear amplifying circuit can operate in a desired operating point, the desired operating point can be selected based on signal to noise ration consideration, non-linearity characteristics and the like.

The reconstruction circuit 80 is illustrated in FIG. 2 as including a low noise amplifier 81(1) that receives the sampled portion of the amplified signal, a differential amplifier 81(2) that is connected to the low noise amplifier 81(1) to provide an analog I-channel signal and an analog Q-channel signal to a down-conversion unit that includes I-channel and Q-channel mixers 82(1) and 82(2), local oscillator 83(1), ninety degrees phase offset 83(2), one or more filters (such as I-channel and Q-channel low pass filters 84(1) and 84(2), band pass filters, high pass filters), and one or more I-channel and Q-channel analog to digital converters 85(1) and 85(2).

The control circuit 90 may be arranged to calculate the error attribute based on a ratio between (i) a difference between a power attribute of the clipped I-channel and Q-channel digital signals and a power attribute of the reconstructed digital I-channel and Q-channel signals; and (ii) the power attribute of the clipped I-channel and Q-channel digital signals.

The control circuit 90 may be arranged to calculate the error attribute by: calculating auto-correlations of the clipped I-channel and Q-channel digital signals to provide auto-correlation results; calculating cross-correlations between the clipped I-channel and Q-channel digital signals and the reconstructed digital I-channel and Q-channel signals to provide cross-correlation results; and calculating a pre-defined relationship between the auto-correlation results and the cross-correlation results.

The device may include I-channel and Q-channel digital multipliers 31 and 32 that precede a clipping circuit 35 and 36 of the input circuit 30; and wherein the control circuit 90 may be arranged to affect an operational parameter of each of the I-channel and Q-channel digital multipliers 31 and 32.

The device may include I-channel and Q-channel digital multipliers 31 and 32 that precede a clipping circuit 35 and 36 of the input circuit 30; and wherein the control circuit 90 is further arranged to affect at least one operational parameter of each of the I-channel and Q-channel digital multipliers 31 and 32.

The control circuit 90 may be arranged to affect the gain of each of the I-channel and Q-channel digital multipliers 31 and 32 and the gain of the non-linear amplifying circuit 60 while maintaining an overall transmission gain of the device substantially unchanged.

The control circuit 90 may be arranged to affect the at least one operational parameter of each of the I-channel and Q-channel digital multipliers 31 and 32 and the at least one operational parameter of the non-linear amplifying circuit 60 while maintaining a value of at least one overall operational parameter of the device substantially unchanged.

The non-linear amplifying circuit 60 may include a non-linear amplifier 62 and a pre-amplifier 62; wherein the control circuit 90 may be arranged to affect an operational parameter of the pre-amplifier 62.

The mixed signal circuit 50 may include at least one pair of I-channel and Q-channel multipliers 31 and 32; wherein the control circuit 90 may be arranged to control at least one operational parameter of at least one pair of I-channel and Q-channel multipliers 31 and 32.

The input circuit 30 may be arranged to apply clipping operations (by clipping circuits 35 and 36) and low-pass filtering operations (by low pass filters 37 and 38) on the I-channel and Q-channel digital input signals to provide the clipped I-channel and Q-channel digital signals; wherein the clipping operations precede the low-pass filtering operations.

The pre-distortion circuit may be arranged to select a selected set of pre-distortion coefficient values, based on attributes of the clipped I-channel and Q-channel digital signals; and to apply the selected set of the pre-distortion coefficient values to provide the pre-distorted I-channel and Q-channel digital signals.

The control circuit 90 may be arranged to affect gains of multiple components of the device while maintaining an operating point of a non-linear amplifier 62 of the non-linear amplifying circuit 60 substantially unchanged.

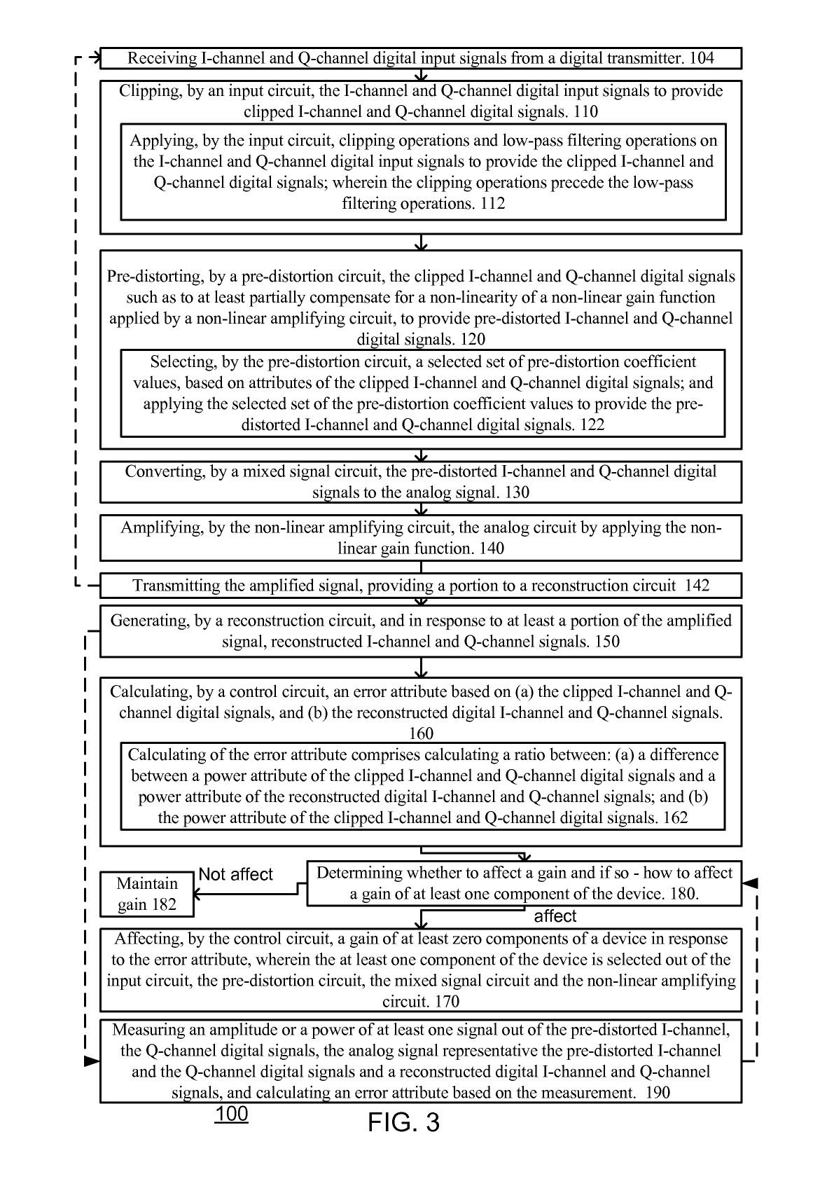

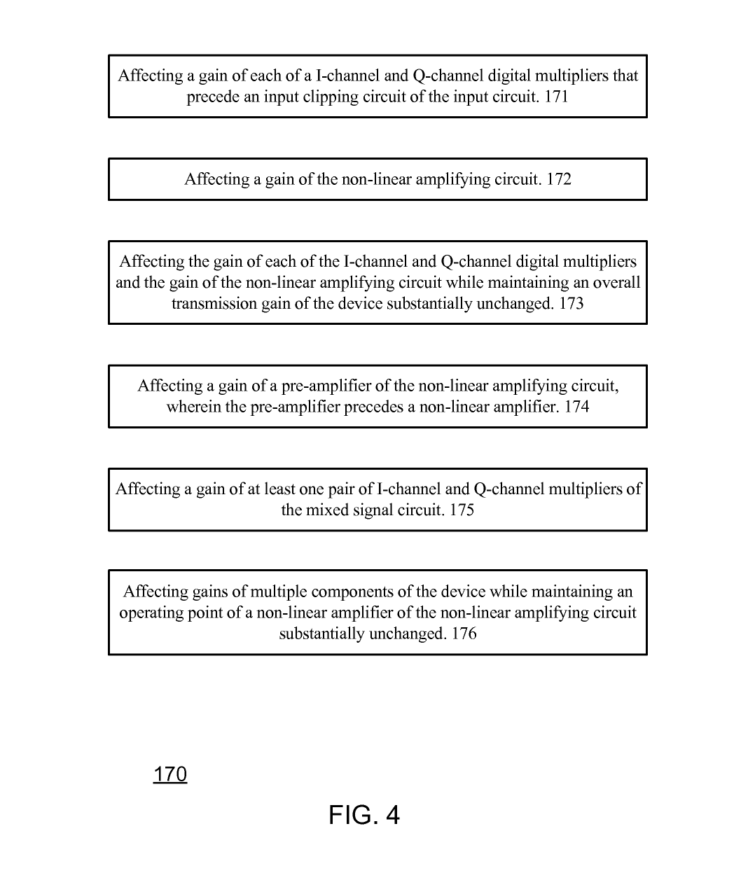

FIG. 3 illustrates method 100 according to an embodiment of the invention. FIG. 4 illustrates stage 170 of method 100 according to an embodiment of the invention.

Method 100 includes a sequence of stages 104, 110, 120, 130, 140 and 142. Stage 142 can be followed by stages 150, 160, 180, 170 and 182. It is noted that stages 150-182 can be repeated during each iteration of stages 104-142 or per multiple iterations of stages 104-142.

It may be beneficial to find a tradeoff between too frequent gain alterations and fewer than desired gain alterations. The tradeoff can be set according to any known gain control algorithms For example, a gain will be affected only if an error attribute (calculated during stage 160) deviates from a desired error attribute by a predefined amount. Yet for another example, a hysteresis can be applied on gain alterations.

Method 100 starts by stage 104 of receiving from a digital transmitter I-channel and Q-channel input signals.

Stage 110 includes clipping, by an input circuit, the I-channel and Q-channel digital input signals to provide clipped I-channel and Q-channel digital signals.

Stage 110 can include a combination of clipping a low pass filtering. Thus, after being clipped a low pass filtering can be applied. This is illustrated by stage 112.

Stage 120 includes pre-distorting, by a pre-distortion circuit, the clipped I-channel and Q-channel digital signals such as to at least partially compensate for a non-linearity of a non-linear gain function applied by a non-linear amplifying circuit, to provide pre-distorted I-channel and Q-channel digital signals. 120

Stage 120 can include stage 122 of selecting, by the pre-distortion circuit, a selected set of pre-distortion coefficient values, based on attributes of the clipped I-channel and Q-channel digital signals and applying the selected set of the pre-distortion coefficient values to provide the pre-distorted I-channel and Q-channel digital signals. The attributes can include phase and amplitude of current and previous clipped I-channel and Q-channel digital signals.

The sets of pre-distortion coefficient values can be generated by calculating Volterra-based approximations of the non-linear gain function. Volterra-based approximations are approximations of Volterra series that can be used to evaluate the non-linearity of a non-linear amplifying circuit. These pre-distortion coefficient values can be values of pre-distortion coefficients that are used to pre-distort digital signals during a pre-distorting process that may be aimed to perform (or at least assist in) a pre-distortion.

The sets of pre-distortion coefficient values can be simulated or otherwise calculated. They can be calculated by feeding, during a test period, the non-linear amplifying circuit with test signals and measuring the spectrum of the amplified signals. The test signals can be pre-distorted before being provided to the non-linear amplifying circuit by applying tested sets of pre-distortion coefficient values, until obtaining desired pre-distortion performance. The sets of pre-distortion coefficient values can be dynamically updated based on the success (or failure) of the pre-distortion applied during method 100.

Stage 130 includes converting, by a mixed signal circuit, the pre-distorted I-channel and Q-channel digital signals to the analog signal. Stage 130 may include, for example, digital to analog converting, low pass filtering, up-conversion, introduction of a ninety degree phase shift and summation.

Stage 140 may include amplifying, by the non-linear amplifying circuit, the analog circuit by applying the non-linear gain function. Stage 140 can include pre-amplifying the analog signal by a pre-amplifier that may have an adjustable gain and may be linear and then amplifying the pre-amplified signal by the non-linear amplifier to provide an output signal.

Stage 142 includes transmitting the amplified signal (for example- by an antenna) and providing a portion of the amplified signal to a reconstruction circuit. The provision to the reconstruction circuit can include directing a fraction of the amplified signal to the reconstruction circuit by a coupler or wirelessly receiving the transmitted amplified signal.

Stage 150 includes generating, by a reconstruction circuit, and in response to at least a portion of the amplified signal, reconstructed I-channel and Q-channel signals. The generating may include trying to reverse the operations performed by the mixed signal circuit (and additionally or alternatively—of other components of the transmission path). It may include, for example, amplification of the amplified signal, down-conversion, low pass filtering, analog to digital conversion and the like.

Stage 160 includes calculating, by a control circuit, an error attribute based on (a) the clipped I-channel and Q-channel digital signals, and (b) the reconstructed digital I-channel and Q-channel signals.

Stage 160 may include stage 162 of calculating of the error attribute comprises calculating a ratio between: (a) a difference between a power attribute of the clipped I-channel and Q-channel digital signals and a power attribute of the reconstructed digital I-channel and Q-channel signals; and (b) the power attribute of the clipped I-channel and Q-channel digital signals.

Stage 180 follows stage 160 and may include determining whether to affect a gain of at least one component of the device and if so- how to affect the gain.

If determining not to change the gain of any component of the system then stage 180 is followed by stage 182 of maintaining the gains unchanged. Else- stage 180 is followed by stage 170.

Stage 170 includes affecting, by the control circuit, a gain of at least one components of a device in response to the error attribute, wherein the at least one component of the device is selected out of the input circuit, the pre-distortion circuit, the mixed signal circuit and the non-linear amplifying circuit. The affecting is responsive to the determination of stage 180.

Stage 170 may include at least one of the following or a combination thereof, all illustrated in FIG. 4:
i. Affecting (171) a gain of each of a I-channel and Q-channel digital multipliers that precede the input clipping circuit.
ii. Affecting (172) a gain of the non-linear amplifying circuit.
iii. Affecting (173) the gain of each of the I-channel and Q-channel digital multipliers and the gain of the non-linear amplifying circuit while maintaining an overall transmission gain of the device substantially unchanged.
iv. Affecting (174) a gain of a pre-amplifier of the non-linear amplifying circuit, wherein the pre-amplifier precedes a non-linear amplifier.
v. Affecting (175) a gain of at least one pair of I-channel and Q-channel multipliers of the mixed signal circuit.
vi. Affecting (176) gains of multiple components of the device while maintaining an operating point of a non-linear amplifier of the non-linear amplifying circuit substantially unchanged. Thus, the non-linear amplifying circuit can operate in a desired operating point, the desired operating point can be selected based on signal to noise ration consideration, non-linearity characteristics and the like.

Method 100 can include stage 190 of (a) measuring an amplitude or a power of at least one signal out of the pre-distorted I-channel, the Q-channel digital signals, the analog signal representative the pre-distorted I-channel and the Q-channel digital signals and a reconstructed digital I-channel and Q-channel signals, and (b) calculating an error attribute based on the measurement.

This measurement (stage 190) can be executed in addition or instead of the calculating (stage 160) of the error attribute based on (a) the clipped I-channel and Q-channel digital signals, and (b) the reconstructed digital I-channel and Q-channel signals. The measuring and affecting of gain can be repeated multiple times until finding an optimal or sub-optimal gain.

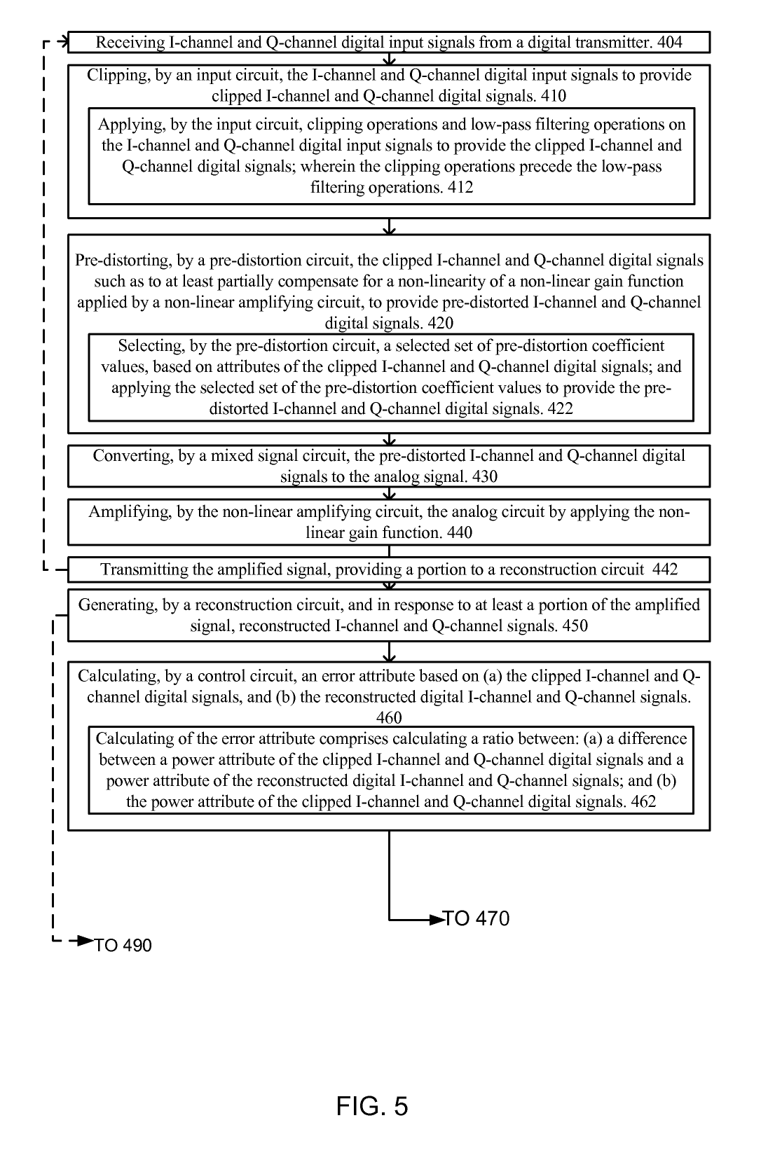

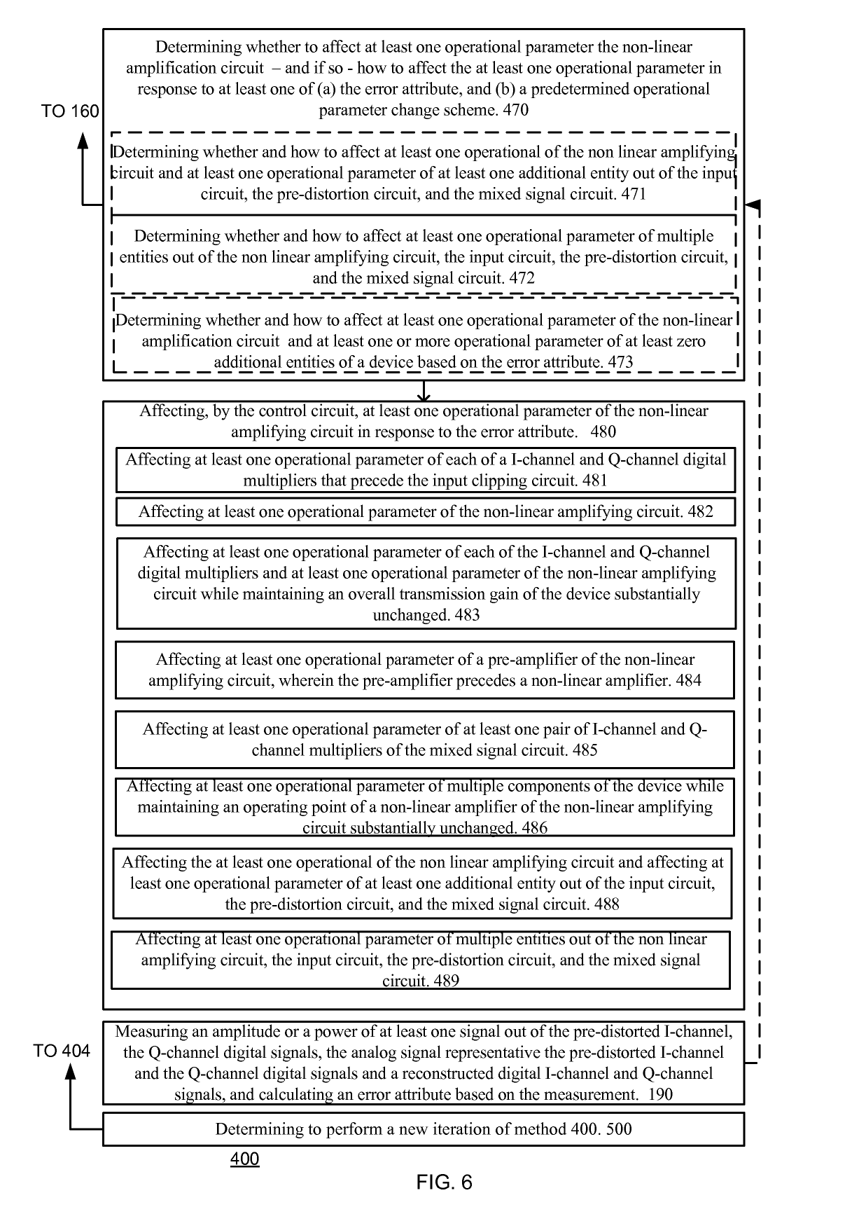

FIGS. 5 and 6 illustrate method 400 according to an embodiment of the invention.

Method 400 may start by stage 404 of receiving I-channel and Q-channel digital input signals from a digital transmitter.

Method 400 includes a sequence of stages 404, 410, 420, 430, 440 and 442. Stage 442 can be followed by stages 450, 460, 470, 480, 490 and 500. It is noted that stages 450-182 can be repeated during each iteration of stages 404-142 or per multiple iterations of stages 404-142.

It may be beneficial to find a tradeoff between too frequent gain alterations and fewer than desired gain alterations. The tradeoff can be set according to any known gain control algorithms For example, a gain will be affected only if an error attribute (calculated during stage 460) deviates from a desired error attribute by a predefined amount. Yet for another example, a hysteresis can be applied on gain alterations.

Method 400 starts by stage 404 of receiving from a digital transmitter I-channel and Q-channel input signals.

Stage 410 includes clipping, by an input circuit, the I-channel and Q-channel digital input signals to provide clipped I-channel and Q-channel digital signals.

Stage 410 can include a combination of clipping a low pass filtering. Thus, after being clipped a low pass filtering can be applied. This is illustrated by stage 412.

Stage 420 includes pre-distorting, by a pre-distortion circuit, the clipped I-channel and Q-channel digital signals such as to at least partially compensate for a non-linearity of a non-linear gain function applied by a non-linear amplifying circuit, to provide pre-distorted I-channel and Q-channel digital signals. 420

Stage 420 can include stage 422 of selecting, by the pre-distortion circuit, a selected set of pre-distortion coefficient values, based on attributes of the clipped I-channel and Q-channel digital signals and applying the selected set of the pre-distortion coefficient values to provide the pre-distorted I-channel and Q-channel digital signals. The attributes can include phase and amplitude of current and previous clipped I-channel and Q-channel digital signals.

The sets of pre-distortion coefficient values can be generated by calculating Volterra-based approximations of the non-linear gain function. Volterra-based approximations are approximations of Volterra series that can be used to evaluate the non-linearity of a non-linear amplifying circuit. These pre-distortion coefficient values can be values of pre-distortion coefficients that are used to pre-distort digital signals during a pre-distorting process that may be aimed to perform (or at least assist in) a pre-distortion.

The sets of pre-distortion coefficient values can be simulated or otherwise calculated. They can be calculated by feeding, during a test period, the non-linear amplifying circuit with test signals and measuring the spectrum of the amplified signals. The test signals can be pre-distorted before being provided to the non-linear amplifying circuit by applying tested sets of pre-distortion coefficient values, until obtaining desired pre-distortion performance. The sets of pre-distortion coefficient values can be dynamically updated based on the success (or failure) of the pre-distortion applied during method 400.

Stage 430 includes converting, by a mixed signal circuit, the pre-distorted I-channel and Q-channel digital signals to the analog signal. Stage 430 may include, for example, digital to analog converting, low pass filtering, up-conversion, introduction of a ninety degree phase shift and summation.

Stage 440 may include amplifying, by the non-linear amplifying circuit, the analog circuit by applying the non-linear gain function. Stage 440 can include pre-amplifying the analog signal by a pre-amplifier that may have an adjustable gain and may be linear and then amplifying the pre-amplified signal by the non-linear amplifier to provide an output signal.

Stage 442 includes transmitting the amplified signal (for example- by an antenna) and providing a portion of the amplified signal to a reconstruction circuit. The provision to the reconstruction circuit can include directing a fraction of the amplified signal to the reconstruction circuit by a coupler or wirelessly receiving the transmitted amplified signal.

Stage 450 includes generating, by a reconstruction circuit, and in response to at least a portion of the amplified signal, reconstructed I-channel and Q-channel signals. The generating may include trying to reverse the operations performed by the mixed signal circuit (and additionally or alternatively—of other components of the transmission path). It may include, for example, amplification of the amplified signal, down-conversion, low pass filtering, analog to digital conversion and the like.

Stage 460 includes calculating, by a control circuit, an error attribute based on at least one of the (a) the clipped I-channel and Q-channel digital signals, and (b) the reconstructed digital I-channel and Q-channel signals.

Stage 460 may include stage 462 of calculating of the error attribute comprises calculating a ratio between: (a) a difference between a power attribute of the clipped I-channel and Q-channel digital signals and a power attribute of the reconstructed digital I-channel and Q-channel signals; and (b) the power attribute of the clipped I-channel and Q-channel digital signals.

Stage 470 may include determining whether to affect at least one operational parameter the non-linear amplification circuit—and if so—how to affect the at least one operational parameter in response to at least one of (a) the error attribute, and (b) a predetermined operational parameter change scheme.

The predetermined operational parameter change scheme can define predefined changes of a value at least one operational parameter in relation about a previously determined value of the at least one operational parameter. This can assist when performing multiple iterations of a calibration process and trying to find the optimal value of the at least parameter while staying in predefined range of changes of said value.

Method 400 can be executed multiple times to provide multiple iterations of a compensation process that includes the calculating (460), determining (470) and affecting (480).

The compensating process may be executed once, in a periodical manner, in a random manner, in a pseudo-random manner, and additionally or alternatively, in response to an event such as a malfunction, increased distortions, changes in an ambient temperature and the like.

The compensating process can include one or more iterations of (i) calculating an error attribute, and (ii) affecting at least one operational parameter of (at least) the non-linear amplification circuit based on the error attribute, based on a predetermined operational parameter change scheme or based on both. [001361 Multiple iterations of stages 460, 480 and 470 can provide multiple error attributes that can be processed to determine the optimal one or more operational parameters. The operational parameters can be changed (for example slightly changed about a working point) until finding a desired (for example- a local optimum) operational parameter. Slight changes can be defined as being a fraction (less than 1/N, wherein N can be 2, 3, 4, 5, 6, 7, 8 or more) of the value of the operational parameter.

The triggering of the multiple repetition of the compensating process is illustrated by stage 500 of determining to perform a new iteration of method 400. Stage 500 can be followed by stage 404.

Stage 470 may include stage 471 of determining whether and how to affect at least one operational of the non linear amplifying circuit and at least one operational parameter of at least one additional entity out of the input circuit, the pre-distortion circuit, and the mixed signal circuit.

Stage 470 may include stage 472 of determining whether and how to affect at least one operational parameter of multiple entities out of the non linear amplifying circuit, the input circuit, the pre-distortion circuit, and the mixed signal circuit.

Stage 470 may include stage 472 of determining whether and how to affect at least one operational parameter of the non-linear amplification circuit 60 and at least one or more operational parameter of at least zero additional entities of a device based on the error attribute.

It is noted that when affecting one or more operational parameter of the non-linear amplification circuit and at least one other entity then the operational parameters affected may change from one entity to another or may be the same. For example, the method can include determining to affect a gain of the non-linear amplification circuit 60 while affecting a bias voltage of the pre-distortion circuit 40.

If determining not to change the gain of any component of the system then stage 470 is followed by stage 460. Else- stage 470 is followed by stage 480.

Stage 480 includes affecting, by the control circuit, at least one operational parameter of the non-linear amplifying circuit in response to the error attribute. Stage 480 may include stage 488 of affecting the at least one operational of the non linear amplifying circuit and affecting at least one operational parameter of at least one additional entity out of the input circuit, the pre-distortion circuit, and the mixed signal circuit.

Stage 480 may include stage 489 of affecting at least one operational parameter of multiple entities out of the non linear amplifying circuit, the input circuit, the pre-distortion circuit, and the mixed signal circuit.

The at least one operational parameter may include a gain, a bias voltage, a saturation power or a combination thereof. The at least one operational parameter can be affected by changing a signal provided such as a current, a voltage or a command.

The affecting is responsive to the determination of stage 470.

Stage 480 may include at least one of the following or a combination thereof, all illustrated in FIG. 4:
i. Affecting (481) at least one operational parameter of each of a I-channel and Q-channel digital multipliers that precede the input clipping circuit.
ii. Affecting (482) at least one operational parameter of the non-linear amplifying circuit.
iii. Affecting (483) at least one operational parameter of each of the I-channel and Q-channel digital multipliers and at least one operational parameter of the non-linear amplifying circuit while maintaining an overall transmission gain of the device substantially unchanged.
iv. Affecting (484) at least one operational parameter of a pre-amplifier of the non-linear amplifying circuit, wherein the pre-amplifier precedes a non-linear amplifier.
v. Affecting (485) at least one operational parameter of at least one pair of I-channel and Q-channel multipliers of the mixed signal circuit.
vi. Affecting (486) at least one operational parameter of multiple components of the device while maintaining an operating point of a non-linear amplifier of the non-linear amplifying circuit substantially unchanged. Thus, the non-linear amplifying circuit can operate in a desired operating point, the desired operating point can be selected based on signal to noise ration consideration, non-linearity characteristics and the like.

Method 400 can include stage 490 of (a) measuring an amplitude or a power of at least one signal out of the pre-distorted I-channel, the Q-channel digital signals, the analog signal representative the pre-distorted I-channel and the Q-channel digital signals and a reconstructed digital I-channel and Q-channel signals, and (b) calculating an error attribute based on the measurement.

This measurement (stage 490) can be executed in addition or instead of the calculating (stage 460) of the error attribute based on (a) the clipped I-channel and Q-channel digital signals, and (b) the reconstructed digital I-channel and Q-channel signals. The measuring and affecting of gain can be repeated multiple times until finding an optimal or sub-optimal gain.

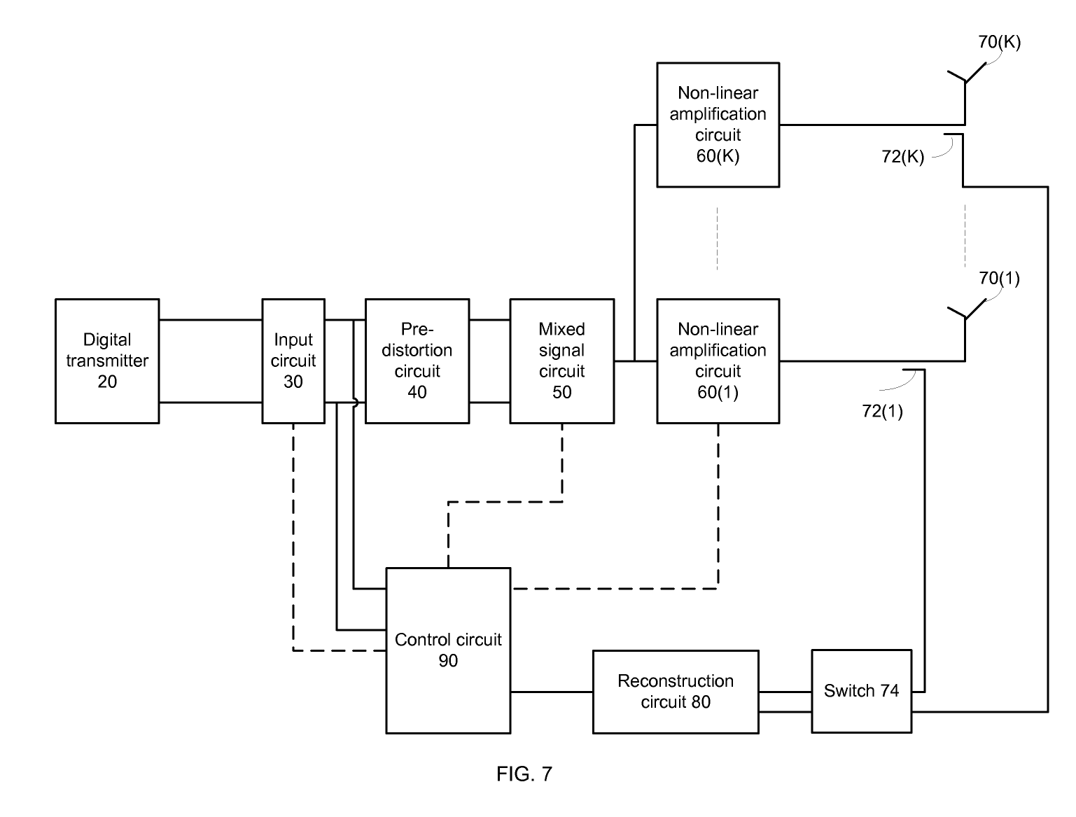

FIG. 7 illustrates device 11 according to another embodiment of the invention.

Instead of having a single non-liner amplifying circuit 60, a single antenna 70 and a single coupler 72, device 11 includes an array of non-linear amplifying circuits 60(1)-60(K), an array of antennas 70(1)-70(K), couplers 72(1)-72(K) and a switch 74 that selects which coupler shall provide its signal to the reconstruction circuit 50. Index K is a positive integer that exceeds one.

For each value of index k (k ranges between 1 and K), a coupler 72(k) provides a fraction of an amplified signal that is sent from non-liner amplifying circuit 60(k) to antenna 70(k). The output of the mixed signal circuit 50 is connected to the inputs of all the non-linear amplifying circuits of the array of non-linear amplifying circuits 60(1)-60(K). The non-linear amplifying circuits of the array of non-linear amplifying circuits 60(1)-60(K) can operate in parallel to each other.

The switch 84 can send to the reconstruction circuit 80 a sample of a selected amplified signal of a selected non-linear amplifying circuit out of 60(1)-60(K), and the reconstruction circuit 80 can be arranged to receive at least a portion of the amplified signal and to generate reconstructed I-channel and Q-channel signals for that selected non-linear amplifying circuit.

The control circuit 90 can be arranged to calculate an error attribute per selected nonlinear amplifying circuit based on (a) the clipped I-channel and Q-channel digital signals, and (b) the reconstructed digital I-channel and Q-channel signals received for the selection of one or more non-linear amplifying circuits.

The control circuit 90 can affect a gain of at least one components of the device in response to at least one error attribute—calculated in response to a selection of a certain non-linear amplifying circuit. The control circuit 90 can affect any gain or any other parameter (supply voltage level, supply current level , Bias Voltage) based upon error attributes calculated in relation to one or more selected non-linear amplifying circuits. For example, the control circuit can calculate the error attributes for each on of the array of non-linear amplifying circuits 60(1)-60(K) and determine the gain or other parameters that will optimize (or improve) the overall performance of the array of non-linear amplifying circuits . The control circuit can also determine not to affect any gain based on the error attribute.

The control circuit 90 can affect one or more parameters that affect a single non-linear amplifying circuit or affect one or more parameters that affect multiple non-linear amplifying circuits. For example, a gain of (of voltage or current supplied to) circuits such as an input circuit 30, a pre-distortion circuit 40 or a mixed signal circuit 50 can be affected. Additionally or alternatively, a gain of (of voltage or current supplied to) circuits such as one or more of the non-linear amplifying circuits can be affected.

The non-linear amplification circuits can be substantially the same, can differ by phase shift, can differ by gain, and the like.

It is noted that there can be multiple input circuits, multiple pre-distortion circuits and, additionally or alternatively, multiple mixed signal circuits per the array of non-linear amplifying circuits. The number of the latter (K) is expected to exceed the number of the former circuits.

The switch 74 can be controlled by the control circuit 90. The control circuit 90 can scan the non-linear amplifying circuits in a sequential manner, in a random manner or in a pseudo-random manner. The scanning can be executed during a calibration phase, during the regular operation of the device or both.

The control circuit 90 can affect one or more parameters based upon an evaluation of error signals relating to only a subset of the entire array of non-linear amplifying circuits 60(1)-60(K). Thus, it can affect the gain (or any other parameter) relating to one or more non-linear amplifying circuits based upon error attribute obtained from measurements obtained from a selection of one or more other non-linear amplifying circuits.

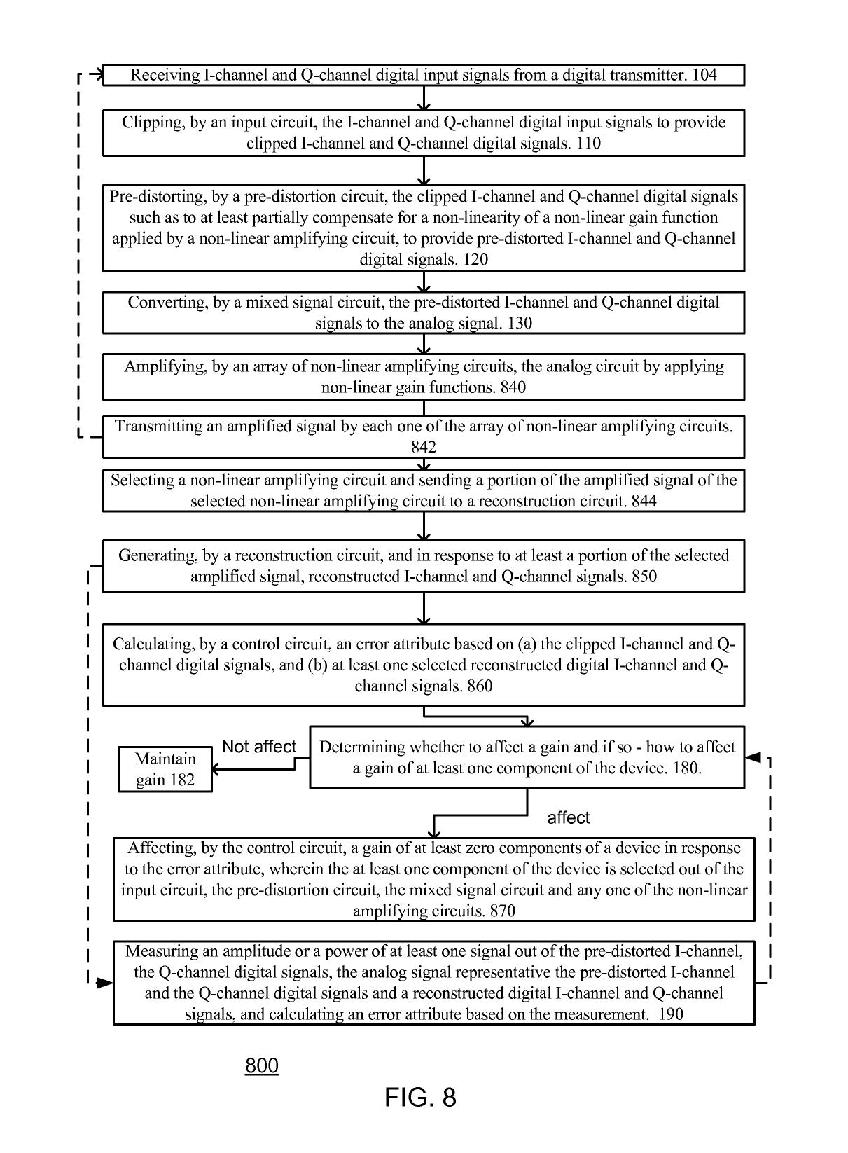

FIG. 8 illustrates method 800 according to an embodiment of the invention.

Method 800 includes a sequence of stages 104, 110, 120, 130, 840, 842 and 844. Stage 844 can be followed by stages 850, 860, 180, 870 and 182. It is noted that stages 850, 860, 180, 870 and 182 can be repeated during each iteration of stages 104, 110, 120, 130, 842, 840 and 844 or per multiple iterations of stages 104, 110, 120, 130, 840, 842 and 844. Method 800 may also include stage 190.

It may be beneficial to find a tradeoff between too frequent gain alterations and fewer than desired gain alterations. The tradeoff can be set according to any known gain control algorithms For example, a gain will be affected only if an error attribute (calculated during stage 160) deviates from a desired error attribute by a predefined amount. Yet for another example, a hysteresis can be applied on gain alterations.

Method 800 may start by stage 104 of receiving from a digital transmitter I-channel and Q-channel input signals.

Stage 110 includes clipping, by an input circuit, the I-channel and Q-channel digital input signals to provide clipped I-channel and Q-channel digital signals.

Stage 120 includes pre-distorting, by a pre-distortion circuit, the clipped I-channel and Q-channel digital signals such as to at least partially compensate for a non-linearity of a non-linear gain function applied by a non-linear amplifying circuit, to provide pre-distorted I-channel and Q-channel digital signals. 120

Stage 130 includes converting, by a mixed signal circuit, the pre-distorted I-channel and Q-channel digital signals to the analog signal. Stage 130 may include, for example, digital to analog converting, low pass filtering, up-conversion, introduction of a ninety degree phase shift and summation.

Stage 840 may include amplifying, by an array of non-linear amplifying circuits, (such as 60(1)-60(K)) the analog circuit by applying non-linear gain functions.

Stage 842 may include transmitting an amplified signal by each one of the array of non-linear amplifying circuits.

Stage 844 may include selecting a non-linear amplifying circuit and sending a portion of the amplified signal of the selected non-linear amplifying circuit to a reconstruction circuit. Multiple repetitions of stage 844 can result in selecting one non-linear amplifying circuit after the other.

Stage 850 may include generating, by a reconstruction circuit, and in response to at least a portion of the selected amplified signal, reconstructed I-channel and Q-channel signals.

Stage 860 may include calculating, by a control circuit, an error attribute based on (a) the clipped I-channel and Q-channel digital signals, and (b) at least one selected reconstructed digital I-channel and Q-channel signals.

Stage 180 follows stage 860 and may include determining whether to affect a gain of at least one component of the device and if so- how to affect the gain.

If determining not to change the gain of any component of the system then stage 180 is followed by stage 182 of maintaining the gains unchanged. Else- stage 180 is followed by stage 870.

Stage 870 includes

The affecting is responsive to the determination of stage 180.

Stage 170 may include at least one of the following or a combination thereof:
i. Affecting a gain of each of a I-channel and Q-channel digital multipliers that precede the input clipping circuit.
ii. Affecting a gain of one or more of the non-linear amplifying circuits.
iii. Affecting the gain of each of the I-channel and Q-channel digital multipliers and the gain of one or more of the non-linear amplifying circuits while maintaining an overall transmission gain of the device substantially unchanged.
iv. Affecting a gain of one or more pre-amplifiers of one or more non-linear amplifying circuits, wherein any pre-amplifier precedes a non-linear amplifier.
v. Affecting a gain of at least one pair of I-channel and Q-channel multipliers of the mixed signal circuit.
vi. Affecting gains of multiple components of the device while maintaining an operating point of a non-linear amplifier of the non-linear amplifying circuit substantially unchanged. Thus, the non-linear amplifying circuit can operate in a desired operating point, the desired operating point can be selected based on signal to noise ration consideration, non-linearity characteristics and the like.

Method 100 can include stage 190 of (a) measuring an amplitude or a power of at least one signal out of the pre-distorted I-channel, the Q-channel digital signals, the analog signal representative the pre-distorted I-channel and the Q-channel digital signals and a reconstructed digital I-channel and Q-channel signals, and (b) calculating an error attribute based on the measurement.

This measurement (stage 190) can be executed in addition or instead of the calculating (stage 860) of the error attribute. The measuring and affecting of gain can be repeated multiple times until finding an optimal or sub-optimal gain.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A device, comprising:
a non-linear amplifying circuit arranged to apply a non-linear gain function on an analog signal to provide an amplified signal;
an input circuit, arranged to clip I-channel and Q-channel digital input signals supplied from a digital transmitter, to provide clipped I-channel and Q-channel digital signals;
a pre-distortion circuit, arranged to pre-distort the clipped I-channel and Q-channel digital signals such as to at least partially compensate for a non-linearity of the non-linear gain function, to provide pre-distorted I-channel and Q-channel digital signals;
a mixed signal circuit for converting the pre-distorted I-channel and Q-channel digital signals to the analog signal;
a reconstruction circuit, arranged to receive at least a portion of the amplified signal and to generate reconstructed I-channel and Q-channel signals;
a control circuit, arranged to:
calculate an error attribute based on at least one of the (a) the clipped I-channel and Q-channel digital signals, and (b) the reconstructed digital I-channel and Q-channel signals; and
to affect at least one operational parameter of the non-linear amplifying circuit in response to at least one of (a) the error attribute, and (b) a predetermined operational parameter change scheme.

2. The device according to claim 1, wherein the control circuit is arranged to affect at least one of (a) at least one operational parameter of the non linear amplifying circuit and (b) at least one operational parameter of at least one additional entity out of the input circuit, the pre-distortion circuit, and the mixed signal circuit.

3. The device according to claim 2, wherein the at least one operational parameter comprises a gain.

4. The device according to claim 2, wherein the at least one operational parameter comprises a bias voltage.

5. The device according to claim 2, wherein the at least one operational parameter comprises a level of a saturation power.

6. The device according to claim 1, wherein the control circuit is arranged to perform multiple iterations of affecting the at least one operational parameter and calculating the error attribute.

7. The device according to claim 1, wherein the control circuit is arranged to perform multiple iterations of affecting the at least one operational parameter and calculating the error attribute until finding an optimal value of the at least one operational parameter.

8. The device according to claim 1, wherein the control circuit is arranged to affect at least one operational parameter of multiple entities out of the non linear amplifying circuit, the input circuit, the pre-distortion circuit, and the mixed signal circuit.

9. The device according to claim 1, wherein the control circuit is arranged to calculate the error attribute based on a ratio between
a. a difference between a power attribute of the clipped I-channel and Q-channel digital signals and a power attribute of the reconstructed digital I-channel and Q-channel signals; and
b. the power attribute of the clipped I-channel and Q-channel digital signals.

10. The device according to claim 1, wherein the control circuit is arranged to calculate the error attribute by:
calculating auto-correlations of the clipped I-channel and Q-channel digital signals to provide auto-correlation results;
calculating cross-correlations between the clipped I-channel and Q-channel digital signals and the reconstructed digital I-channel and Q-channel signals to provide cross-correlation results; and
calculating a pre-defined relationship between the auto-correlation results and the cross-correlation results.

11. The device according to claim 1, further comprising I-channel and Q-channel digital multipliers that precede a clipping circuit of the input circuit; and wherein the control circuit is arranged to affect an operational parameter of each of the I-channel and Q-channel digital multipliers.

12. The device according to claim 1, further comprising I-channel and Q-channel digital multipliers that precede a clipping circuit of the input circuit; and wherein the control circuit is further arranged to affect at least one operational parameter of each of the I-channel and Q-channel digital multipliers.

13. The device according to claim 12, wherein the control circuit is arranged to affect the gain of each of the I-channel and Q-channel digital multipliers and the gain of the non-linear amplifying circuit while maintaining an overall transmission gain of the device substantially unchanged.

14. The device according to claim 12, wherein the control circuit is arranged to affect the at least one operational parameter of each of the I-channel and Q-channel digital multipliers and the at least one operational parameter of the non-linear amplifying circuit while maintaining a value of at least one overall operational parameter of the device substantially unchanged.

15. The device of claim 1, wherein the non-linear amplifying circuit comprises a non-linear amplifier and a pre-amplifier; wherein the control circuit is arranged to affect an operational parameter of the pre-amplifier.

16. The device according to claim 1, wherein the mixed signal circuit comprises at least one pair of I-channel and Q-channel multipliers; wherein the control circuit is arranged to control at least one operational parameter of at least one pair of I-channel and Q-channel multipliers.

17. The device according to claim 1, wherein the input circuit is arranged to apply clipping operations and low-pass filtering operations on the I-channel and Q-channel digital input signals to provide the clipped I-channel and Q-channel digital signals;
wherein the clipping operations precede the low-pass filtering operations.

18. The device according to claim 1, wherein the pre-distortion circuit is arranged to select a selected set of pre-distortion coefficient values, based on attributes of the clipped I-channel and Q-channel digital signals; and to apply the selected set of the pre-distortion coefficient values to provide the pre-distorted I-channel and Q-channel digital signals.

19. The device according to claim 1, wherein the control circuit is arranged to affect gains of multiple components of the device while maintaining an operating point of a non-linear amplifier of the non-linear amplifying circuit substantially unchanged.

20. A method for generating an amplified signal, comprising:
clipping, by an input circuit, I-channel and Q-channel digital input signals supplied from a digital transmitter, to provide clipped I-channel and Q-channel digital signals;
pre-distorting, by a pre-distortion circuit, the clipped I-channel and Q-channel digital signals such as to at least partially compensate for a non-linearity of a non-linear gain function applied by a non-linear amplifying circuit, to provide pre-distorted I-channel and Q-channel digital signals;
converting, by a mixed signal circuit, the pre-distorted I-channel and Q-channel digital signals to the analog signal;
amplifying, by the non-linear amplifying circuit, the analog circuit by applying the non-linear gain function;
generating, by a reconstruction circuit, and in response to at least a portion of the amplified signal, reconstructed I-channel and Q-channel signals;
calculating, by a control circuit, an error attribute based on at least one of the (a) the clipped I-channel and Q-channel digital signals, and (b) the reconstructed digital I-channel and Q-channel signals; and
affecting, by the control circuit, at least one operational parameter of the non-linear amplifying circuit in response at least one of (a) the error attribute, and (b) a predetermined operational parameter change scheme.

21. The method according to claim 20, comprising affecting at least one out of (a) at least one operational of the non linear amplifying circuit and (b) at least one operational parameter of at least one additional entity out of the input circuit, the pre-distortion circuit, and the mixed signal circuit.

22. The method according to claim 21, wherein the at least one operational parameter comprises a gain.

23. The method according to claim 21, wherein the at least one operational parameter comprises a bias voltage.

24. The method according to claim 21, wherein the at least one operational parameter comprises a level of a saturation power.

25. The method according to claim 20, comprising performing multiple iterations of affecting the at least one operational parameter and calculating the error attribute.

26. The method according to claim 20, comprising performing multiple iterations of affecting the at least one operational parameter and calculating the error attribute until finding an optimal value of the at least one operational parameter.

27. The method according to claim 20, comprising affecting at least one operational parameter of multiple entities out of the non linear amplifying circuit, the input circuit, the pre-distortion circuit, and the mixed signal circuit.

28. The method according to claim 20, comprising calculating the error attribute based on a ratio between
a. a difference between a power attribute of the clipped I-channel and Q-channel digital signals and a power attribute of the reconstructed digital I-channel and Q-channel signals; and
b. the power attribute of the clipped I-channel and Q-channel digital signals.

29. The method according to claim 20, comprising calculating the error attribute by:
calculating auto-correlations of the clipped I-channel and Q-channel digital signals to provide auto-correlation results;
calculating cross-correlations between the clipped I-channel and Q-channel digital signals and the reconstructed digital I-channel and Q-channel signals to provide cross-correlation results; and
calculating a pre-defined relationship between the auto-correlation results and the cross-correlation results.

30. The method according to claim 20, wherein the input circuit comprises a clipping circuit that is preceded by I-channel and Q-channel digital multipliers; wherein the method comprises affecting an operational parameter of each of the I-channel and Q-channel digital multipliers.

31. The method according to claim 20, wherein the input circuit comprises a clipping circuit that is preceded by I-channel and Q-channel digital multipliers ; wherein the method comprises affecting at least one operational parameter of each of the I-channel and Q-channel digital multipliers.

32. The method according to claim 31, comprising affecting the gain of each of the I-channel and Q-channel digital multipliers and the gain of the non-linear amplifying circuit while maintaining an overall transmission gain of the device substantially unchanged.

33. The method according to claim 31, comprising affecting the at least one operational parameter of each of the I-channel and Q-channel digital multipliers and the at least one operational parameter of the non-linear amplifying circuit while maintaining a value of at least one overall operational parameter of the device substantially unchanged.

34. The method according to claim 20, wherein the non-linear amplifying circuit comprises a non-linear amplifier and a pre-amplifier; wherein the method comprises affecting an operational parameter of the pre-amplifier.

35. The method according to claim 20, wherein the mixed signal circuit comprises at least one pair of I-channel and Q-channel multipliers; wherein the method comprises controlling at least one operational parameter of at least one pair of I-channel and Q-channel multipliers.

36. The method according to claim 20, comprising applying clipping operations and low-pass filtering operations on the I-channel and Q-channel digital input signals to provide the clipped I-channel and Q-channel digital signals; wherein the clipping operations precede the low-pass filtering operations.

37. The method according to claim 20, comprising selecting a selected set of pre-distortion coefficient values, based on attributes of the clipped I-channel and Q-channel digital signals; and to applying the selected set of the pre-distortion coefficient values to provide the pre-distorted I-channel and Q-channel digital signals.

38. The method according to claim 20, comprising affecting gains of multiple components of the device while maintaining an operating point of a non-linear amplifier of the non-linear amplifying circuit substantially unchanged.

39. The device according to claim 1 comprising multiple non-linear amplifying circuits, each arranged to apply a non-linear gain function on an analog signal to provide an amplified signal; and wherein the control circuit is arranged to calculate at least one error attribute based on at least one of the (a) the clipped I-channel and Q-channel digital signals, and (b) reconstructed digital I-channel and Q-channel signals that are responsive to a selection of at least two non-linear amplification circuits; and to affect at least one operational parameter of the non-linear amplifying circuit in response to at least one of (a) the at least one error attribute, and (b) the predetermined operational parameter change scheme.
